(19) United States
(12) Patent Application Publication
(10) Pub. No.: US 2013/0126829 A1
(43) Pub. Date: May 23, 2013

(54) HIGH EFFICIENCY LIGHT EMITTING DIODE

(71) Applicants: Yeo Jin Yoon, Ansan-si (KR); Won Cheol Seo, Ansan-si (KR)

(72) Inventors: Yeo Jin Yoon, Ansan-si (KR); Won Cheol Seo, Ansan-si (KR)

(21) Appl. No.: 13/812,944

(22) PCT Filed: Dec. 1, 2010
(86) PCT No.: PCT/KR2010/008560

§ 371 Date: Jan. 29, 2013

(30) Foreign Application Priority Data
Sep. 24, 2010 (KR) 10-2010-0092848

(51) Int. Cl. H01L 33/10

(52) U.S. Cl. CPC H01L 33/10
USPC 257/13

(57) ABSTRACT

A high-efficiency LED includes a substrate, an n-semiconductor layer, an active layer, a p-semiconductor layer, and a transparent electrode layer. The substrate has a plurality of tapered recesses in the underside thereof, the recesses being filled with light-reflecting filler.

### CROSS-REFERENCE TO RELATED APPLICATIONS

This application is the National Stage Entry of International Application No. PCT/KR2010/008560, filed on Dec. 1, 2010, and claims priority from and the benefit of Korean Patent Application No. 10-2010-0092848, filed on Sep. 24, 2010, both of which are hereby incorporated by reference for all purposes as if fully set forth herein

### BACKGROUND

1. Field

The present invention relates to a high-efficiency Light-Emitting Diode (LED), and more particularly, to a high-efficiency LED, which can have a light-reflecting structure to improve the internal reflecting efficiency of a substrate and minimize the amount of light absorbed by an electrode pad, thereby improving light-emitting efficiency.

2. Discussion of the Background

Since the development of a nitride semiconductor light-emitting device (e.g., an LED, a laser diode, or the like made of group III nitride-based compound semiconductor), it has been gaining attention as a major light source of the next generation in a variety of fields such as a display backlight, a camera flash, lighting, and the like. In response to an increase in the fields to which the nitride semiconductor light-emitting device is applied, efforts to improve luminance and light-emitting efficiency are underway.

A blue LED made of nitride-based compound semiconductor, such as GaN, InGaN, AlGaN, AlInGaN, or the like, has an advantage in that it can produce full color. However, since the blue LED is typically grown over an insulating sapphire substrate, both an n-electrode and a p-electrode are disposed on the same side (over a nitride semiconductor that is produced by crystal growth) unlike existing LEDs using a conductive substrate, and thus its drawback is a reduced light-emitting area. In addition, since a p-type nitride semiconductor such as p-GaN has a great work function and a high resistance, a p-electrode metal (e.g., a bonding pad or an electrode pad) cannot be used directly over the p-type nitride semiconductor, and a transparent electrode is deposited over a p-type nitride semiconductor layer in an intention to form an ohmic contact and for the purpose of current spreading.

As for the properties of the sapphire substrate used as a growth substrate, it is hard and transparent to light, which is emitted from an active layer formed thereover. The sapphire substrate is machined to be thin at 100 μm or less and a chip is separated using a laser or a diamond chip. Due to the hardness, the sapphire substrate is machined to be thin in order to separate the sapphire substrate, and light, which passed through the sapphire substrate, is reflected by a reflecting material coat applied over the underside of the sapphire substrate.

However, the LED of the related art has a problem in that a portion of light, which was emitted from the active layer and entered the sapphire substrate, is trapped inside the sapphire substrate due to inferior reflecting efficiency. This not only worsens the light-emitting efficiency of the LED, but also generates heat.

In order to improve the light-emitting efficiency of the LED, a method of forming a pattern over the sapphire substrate was proposed.

FIG. 5 is a cross-sectional view showing an LED of the related art.

An LED 50 includes a substrate 510, which has a concave-convex pattern formed in the upper portion thereof to reflect incident light. A buffer layer 520 is formed over the substrate 510 for the purpose of lattice match. An n-semiconductor layer 530 is formed over the buffer layer 520, an active layer 540 is formed over the n-semiconductor layer 530, a p-semiconductor layer 550 is formed over the active layer 540, a transparent electrode layer 560 is formed over the p-semiconductor layer 550, and an electrode pad 570 is formed on the transparent electrode layer 560. In addition, an electrode pad 580 is formed on the n-semiconductor layer 530.

In the LED 50 of the related art, a surface concave-convex structure 522 of several tm is formed over the upper surface of the substrate in order to improve light extraction from the sapphire substrate 510. However, this structure has a problem of limited light extraction efficiency.

In the meantime, in the LED 50 of the related art, when light emitted from the active layer 540 is emitted to the outside through the transparent electrode layer 560, since the electrode pad 570 formed over the transparent electrode layer 560 is a metal layer, light does not pass through but is absorbed by the electrode pad 570, thereby leading to light loss.

### SUMMARY

The present invention has been made to solve the foregoing problems with the related art, and therefore the present invention is to provide a high-efficiency Light-Emitting Diode (LED) that can minimize the amount of light, which is absorbed by an electrode pad, and light, which is not emitted to the outside from a substrate.

According to an aspect of the present invention, the high-efficiency LED includes a substrate, an n-semiconductor layer, an active layer, a p-semiconductor layer, and a transparent electrode layer. The substrate has a plurality of tapered recesses in the underside thereof, the recesses being filled with light-reflecting filler.

It is preferable that the depth of the recesses be ⅓ to ½ of the thickness of the substrate.

It is preferable that the thickness of the substrate be from 150 μm to 250 μm.

It is preferable that the light-emitting filler be one selected from the group consisting of titanium dioxide (TiO₂), lead carbonate (PbCO₃), silica (SiO₂), zirconia (ZrO₂), lead oxide (PbO), alumina (Al₂O₃), tin oxide (ZnO), antimony trioxide (Sb₂O₃), and combinations thereof.

It is preferable that the side surfaces of the tapered recesses have an inclination from 40° to 70°.

It is preferable that the substrate have a concave-convex pattern on the upper portion thereof.

It is preferable that the substrate be a sapphire substrate.

It is preferred to further comprise a reflecting layer formed under an electrode pad, which is formed on the transparent electrode layer.

It is preferable that the reflecting layer be formed between the transparent electrode layer and the electrode pad.

It is preferable that the transparent electrode layer be formed under the electrode pad and has a concave-convex configuration.

It is preferred to further comprise a reflecting layer formed in an area on the p-semiconductor layer, corresponding to the electrode pad, and the transparent electrode layer be formed to cover the reflecting layer.

It is preferable that the electrode pad have extensions extending in a horizontal direction from opposite edges thereof, and the reflecting layer be formed under the extensions.

It is preferable that the reflecting layer be a Distributed Bragg Reflector (DBR).

The high-efficiency LED according to exemplary embodiments of the invention forms the light-reflecting structures on the substrate and the electrode pad in order to minimize the amount of light absorbed by the electrode pad and maximize the internal reflecting efficiency of the substrate, so that the amount of light, which does not exit to the outside, is minimized, thereby improving the light-emitting efficiency thereof.

### BRIEF DESCRIPTION OF THE DRAWINGS

FIG. 1 is a cross-sectional view showing a high-efficiency LED according to an exemplary embodiment of the invention;

FIG. 2 is an enlarged cross-sectional view of part A of FIG. 1 in which an electrode pad is formed;

FIG. 3 is a top plan view of the high-efficiency LED shown in FIG. 1;

FIG. 4 is a cross-sectional view showing a high-efficiency LED according to another exemplary embodiment of the invention; and

FIG. 5 is a cross-sectional view showing an LED of the related art.

### DETAILED DESCRIPTION OF THE ILLUSTRATED EMBODIMENTS

The present invention will now be described more fully hereinafter with reference to the accompanying drawings, in which exemplary embodiments thereof are shown, so that this disclosure will fully convey the scope of the present invention to those skilled in the art. This invention can, however, be embodied in many different forms and should not be construed to be limited to the embodiments set forth herein.

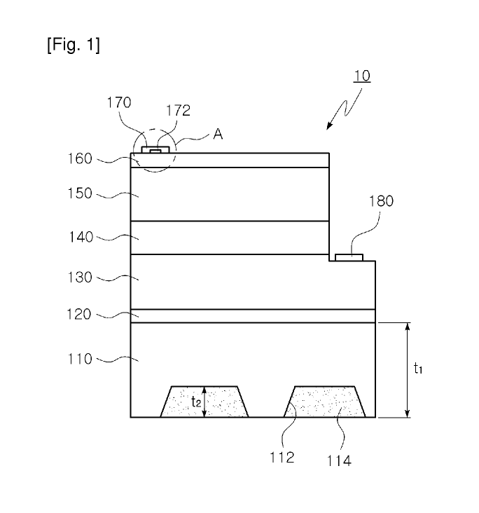

First, a high-efficiency Light-Emitting Diode (LED) according to an exemplary embodiment of the invention is described with reference to FIG. 1.

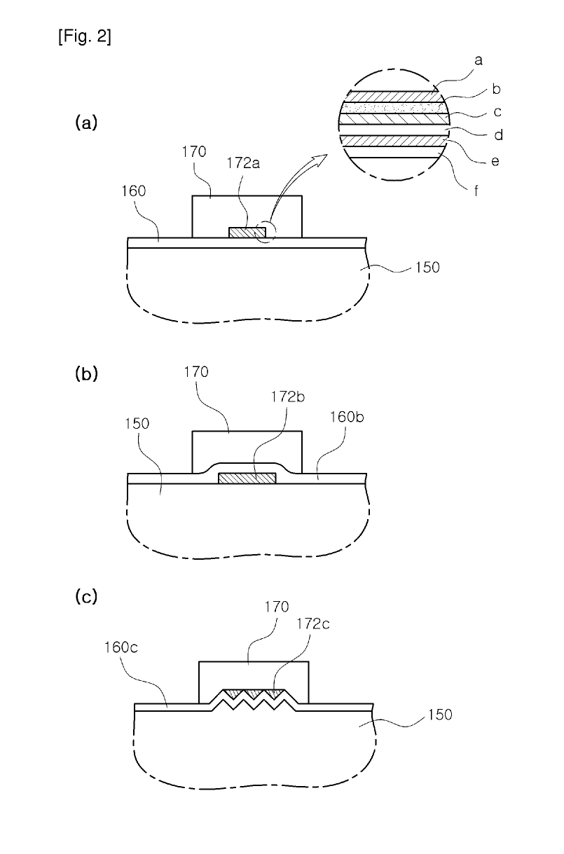

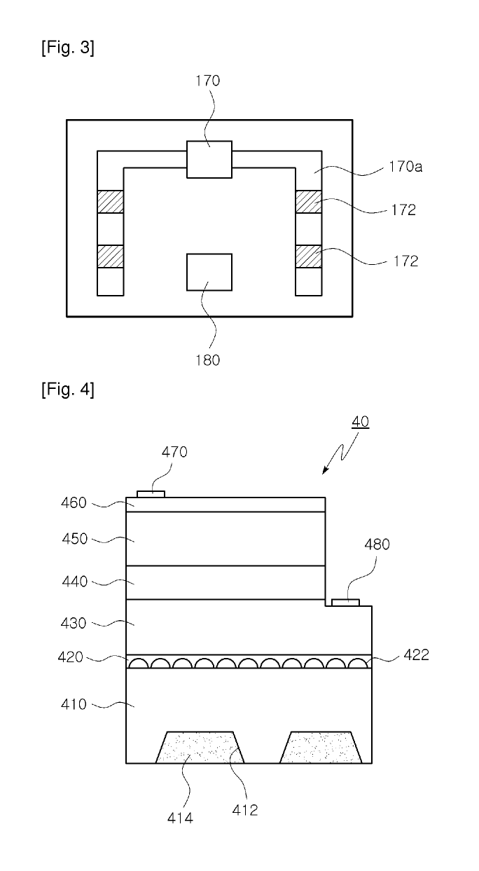

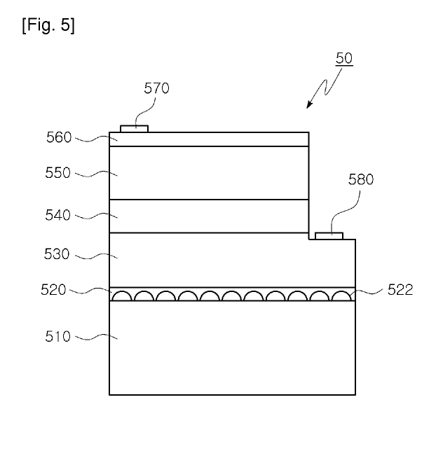

FIG. 1 is a cross-sectional view showing a high-efficiency LED according to an exemplary embodiment of the invention, FIG. 2 is an enlarged cross-sectional view of part A of FIG. 1 in which an electrode pad is formed, and FIG. 3 is a top plan view of the high-efficiency LED shown in FIG. 1.

As shown in FIG. 1, an LED 10 includes a substrate 110, which has recesses 112 in the underside thereof. A buffer layer 120 is formed over the substrate 110 for the purpose of lattice match. An n-semiconductor layer 130 is formed over the buffer layer 120, an active layer 140 is formed over the n-semiconductor layer 130, a p-semiconductor layer 150 is formed over the active layer 140, a transparent electrode layer 160 is formed over the p-semiconductor layer 150, and an electrode pad 170 is formed over the transparent electrode layer 160. In addition, an electrode pad 180 is formed over the n-semiconductor layer 130.

The substrate 110 is generally used as a sapphire substrate in consideration of lattice match with a nitride semiconductor material, which is grown over the substrate. The sapphire substrate is generally used because it is relatively easy to grow the nitride semiconductor material over the sapphire substrate and the sapphire substrate is stable at a high temperature.

The substrate 110 has a plurality of tapered recesses 112 in the underside thereof, and the recesses 112 are filled with light-reflecting filler 114 in order to facilitate the reflection of light, which is emitted from the active layer 140. Here, the light-reflecting filler 114 can be one selected from among titanium dioxide (TiO₂), lead carbonate (PbCO₃), silica (SiO₂), zirconia (ZrO₂), lead oxide (PbO), alumina (Al₂O₃), tin oxide (ZnO), antimony trioxide (Sb₂O₃), and combinations thereof.

The thickness of the substrate 110 is sufficient to form the recesses 112 in the underside thereof. The thickness is preferably from 150 μm to 250 μm, and more preferably 200 μm.

As shown in FIG. 1, each of the recesses 112 has a tapered configuration that becomes narrower in the direction from the underside of the substrate 110 to the central axis, and is formed to have a depth(t₂) that is ⅓ to ½ of the thickness t₁ of the substrate 110.

Due to inclined side surfaces defined by the tapered configuration, the recess 112 efficiently reflects light, which is emitted from the inside. The higher the inclination of the side surfaces is, the better the reflecting efficiency may be. It is preferable that the inclination be 40° to 70°.

Since the tapered recesses 112 are formed in the underside of the substrate 110 and are filled with the light-reflecting filler 114 as described above, light emitted from the active layer 140 can be reflected from the substrate 110 and then exits to the outside through the transparent electrode layer 160, thereby improving the light-emitting efficiency of the LED 10.

The buffer layer 120 is formed for the purpose of lattice match between the overlying nitride semiconductor layer and the substrate 110, and is formed as a low temperature grain-growth layer made of nitride, such as GaN or AlN, having a typical thickness of tens of nm.

The n-semiconductor layer 130 can be made of n-semiconductor expressed by AlₓIn_{y}Ga_{1-x-y}N (0≦x,y,x+y≦1), and can include an n-cladding layer. That is, the n-semiconductor layer 130 can be made of n-doped nitride semiconductor. For example, the nitride semiconductor can be GaN, AlGaN, or InGaN, and the dopant used in the doping of the n-semiconductor layer 130 can be Si, Ge, Se, Te, C, or the like, and preferably Si.

The active layer 140 is an area that emits light through electron-hole recombination, in which the wavelength of the emitted light is determined according to the types of materials that constitute the active layer 140. The active layer 140 can has a Multiple Quantum Well (MQW) structure in which at least two quantum wells and at least two quantum barriers are stacked or a single quantum well structure. Here, each of the barrier layer and the well layer can be a quaternary compound semiconductor layer, which is expressed by a general formula AlₓIn_{y}Ga_{1-x-y}N (0≦x,y,x+y≦1).

For example, the MQW structure can be formed by growing InGaN layers as well layers and GaN layers as barrier layers. In particular, a blue LED uses an MQW structure made of InGaN/GaN or the like, and an Ultraviolet (UV) LED uses an MQW structure made of GaN/AlGaN, InAlGaN/InAlGaN, InGaN/AlGaN, or the like.

The p-semiconductor layer 150 can be made of p-semiconductor expressed by AlₓIn_{y}Ga_{1-x-y}N (0≦x,y,x+y≦1), and can include an n-cladding layer. That is, the p-semiconductor layer 150 can be made of p-doped nitride semiconductor .Representative examples of the nitride semiconductor may include GaN , AlGaN, and InGaN. The dopant used in the doping of the p-semiconductor layer 150 can be Mg, Zn, Be, or the like, and preferably Mg.

The transparent electrode layer 160 functions as an electrode together with the overlying electrode pad 170, and also functions to emit light, which is generated from the active layer 140, to the outside. Thus, the transparent electrode layer 160 is required to have excellent electrical characteristics, together with characteristics that do not obstruct light emission. The transparent electrode layer 160 can be a Ni/Au, ZnO, or Indium Tin Oxide (ITO) layer.

The electrode pad 170 is a p-electrode, and is formed on one side of the transparent electrode 160, which is formed over the p-semiconductor layer 150. The electrode pad 180 is an n-electrode, and is formed on one side of the n-semiconductor layer 130.

Between the transparent electrode layer 160 and the electrode pad 170, a Distributed Bragg Reflector (DBR) 172 is formed as a reflecting layer in order to minimize the amount of light absorbed by the electrode pad 170.

Since the DBR 172 is formed in the underside of the electrode pad 170 in order to prevent light, emitted from the active layer 140, from being absorbed by the electrode pad 170, it can be formed in a variety of forms in the underside of the electrode pad 170.

For example, as shown in FIG. 2 (a) the DBR 172a can be formed between the transparent electrode 160 and the electrode pad 170. It can be formed on a portion of the area over which the electrode pad 170 is supposed to be formed before the formation of the electrode pad 170 after the transparent electrode 160 is formed over the p-semiconductor layer 150. Preferably, the DBR 172a can be formed on the central portion of the electrode pad 170.

The DBR 172a has multiple dielectric layers a to f having different refractive indices, which serve to insulate electrical current. Thus, the width of the DBR 172a is formed to be smaller than that of the electrode pad 170, and the electrode pad 170 and the transparent electrode layer 160 are electrically connected to each other around the opposite ends of the DBR 172a.

In addition, as shown in FIG. 2 (b), a DBR 172b can be formed on the p-semiconductor layer 150. That is, the DBR 172b is formed on an area of the p-semiconductor layer 150, corresponding to the electrode pad 170, before a transparent electrode layer 160b is formed over the p-semiconductor layer 150 to cover the DBR 172b.

In addition, as shown in FIG. 2 (c), a DBR 172c can be formed between a transparent electrode layer 160c and the electrode pad 170. The transparent electrode layer 160c can be formed under the electrode pad 170 with a concave-convex configuration in order to further improve the reflective index of the DBR 172.

That is, the transparent electrode layer 160c is formed over the p-semiconductor layer 150, with the toothed concave-convex configuration formed in an area over which the electrode pad 170 is formed, and the DBR 172 is formed in valleys of the toothed area.

Since the DBR 172 is formed on the underside of the electrode pad 170 as described above, light emitted from the active layer 140 can exit to the outside through the transparent electrode layer 160, in which the electrode pad 170 is not formed, and be reflected toward the substrate 110 by the DBR 172 in the area, in which the electrode pad 170 is formed. This, as a result, can minimize the amount of light absorbed by the electrode pad 170, thereby further improving the light-emitting efficiency of the LED 10.

In the meantime, as shown in FIG. 3, DBR 172 can be formed under electrode extensions 170a that extend from the electrode pad 170. That is, the electrode extensions 170a extend in the horizontal direction from the opposite edges of the electrode pad 170, thereby preventing the flow of electrical current, which is generated from the underside of the electrode pad 170, from being crowded. Since the electrode extensions 170a absorb light, which is emitted from the active layer 140, like the electrode pad 170, the DBR 172 is formed on portions of the electrode extensions 170a.

Although the DBR 172 can be formed on some portions of the electrode extensions 170a as shown in FIG. 3, this is not intended to be limiting. The DBR 172 can be formed over the entire portions of the electrode extensions 170a. The position of the DBR 172 can vary depending on the structure of the transparent electrode layer 160 and the electrode pad 170 as shown in FIG. 2 (a) to (c).

Since the DBR 172 is formed not only on the electrode pad 170 but also on some or entire portions of the electrode extensions 170a as described above, it can reduce the amount of light absorbed by the electrode pad 170 and the electrode extensions 170a, thereby further improving the light-emitting efficiency of the LED 10.

FIG. 4 is a cross-sectional view showing a high-efficiency LED according to another exemplary embodiment of the invention.

The configuration of this embodiment is the same as that of the foregoing embodiment, excepting a pattern formed over the substrate 410. Therefore, descriptions of the same components are omitted herein.

As shown in FIG. 4, a substrate 410 has recesses 412, which are filled with light-reflecting fillers 414, and a concave-convex pattern is formed on the upper portion of the substrate 410 in order to reflect light from entering the substrate 410.

The substrate 410 can be a Patterned Sapphire Substrate (PSS). Although the concave-convex pattern was illustrated, by way of example, in this embodiment, this is not intended to be limiting. Rather, the pattern can be formed by etching the substrate 410 or by applying a metal layer over the upper portion of the substrate 410.

As described above, the concave-convex pattern formed on the upper portion of the substrate 410 can further increase the reflection of light, which is emitted from the active layer 440 and is directed toward the underside of the substrate 410, thereby further improving the light-emitting efficiency of the LED 40.

While the present invention has been shown and described with reference to the certain exemplary embodiments thereof, it will be apparent to those skilled in the art that various changes in form and details may be made therein without departing from the spirit and scope of the present invention and such changes fall within the scope of the appended claims.

1. A high-efficiency light-emitting diode comprising:
a substrate having a first side, an opposing second side, and tapered recesses formed in the second side;
an n-semiconductor layer disposed on the first side of the substrate;
an active layer disposed on the n-semiconductor layer;
a p-semiconductor layer disposed on the active layer;
a transparent electrode layer disposed on the p-semiconductor layer; and,
a light-reflecting filler disposed in the recesses.

2. The high-efficiency light-emitting diode according to claim 1, wherein the recesses have a depth that is ⅓ to ½ of the thickness of the substrate.

3. The high-efficiency light-emitting diode according to claim 1, wherein the thickness of the substrate is from 150 μm to 250 μm.

4. The high-efficiency light-emitting diode according to claim 1, wherein the light-emitting filler is one selected from the group consisting of TiO₂, PbCO₃, SiO₂, ZrO₂, PbO, Al₂O₃, ZnO, Sb₂O₃, and any combinations thereof.

5. The high-efficiency light-emitting diode according to claim 1, wherein side surfaces of the tapered recesses have an inclination of from 40° to 70°, with respect to the plane of the second surface.

6. The high-efficiency light-emitting diode according to claim 1, wherein the substrate has a concave-convex pattern on the first surface thereof.

7. The high-efficiency light-emitting diode according to claim 1, wherein the substrate is a sapphire substrate.

8. The high-efficiency light-emitting diode according to claim 1, further comprising:
an electrode pad formed on the transparent electrode layer; and
a reflecting layer disposed under the electrode pad.

9. The high-efficiency light-emitting diode according to claim 8, wherein the reflecting layer is disposed between the transparent electrode layer and the electrode pad.

10. The high-efficiency light-emitting diode according to claim 9, wherein the transparent electrode layer is disposed under the electrode pad and has a concave-convex configuration.

11. The high-efficiency light-emitting diode according to claim 1, further comprising a reflecting layer formed on a portion of the p-semiconductor layer that corresponds to the electrode pad,
wherein the transparent electrode layer covers is formed to cover the reflecting layer.

12. The high-efficiency light-emitting diode according to claim 8, wherein:
the electrode pad comprises extensions that extend from opposing edges thereof; and
the reflecting layer is disposed under the extensions.

13. The high-efficiency light-emitting diode according to claim 8, wherein the reflecting layer is a Distributed Bragg Reflector.
